(19) United States
(12) Patent Application Publication
(10) Pub. No.: US 2024/0405508 A1
(43) Pub. Date: Dec. 5, 2024

(54) SEMICONDUCTOR LASER DEVICE

(71) Applicant: Mitsubishi Electric Corporation, Tokyo (JP)

(72) Inventor: Shinichi KANEKO, Tokyo (JP)

(73) Assignee: Mitsubishi Electric Corporation, Tokyo (JP)

(21) Appl. No.: 18/718,644

(22) PCT Filed: Apr. 22, 2022
(86) PCT No.: PCT/JP2022/018618

§ 371 Date: Jun. 11, 2024

(51) Int. Cl. H01S 5/024; H01S 5/0231

(52) U.S. Cl. CPC H01S 5/02415; H01S 5/0231; H01S 5/02469

(57) ABSTRACT

A semiconductor laser device includes a stem; a thermoelectric element provided at a position shifted to one side from a center of the stem, on an upper surface of the stem; a semiconductor laser configured to be temperature-controlled by the thermoelectric element; a heat dissipation block including a first portion, a second portion, and a third portion, the first portion being at least partially provided on a rear surface on a side opposite to the upper surface of the stem, the second portion being provided on the rear surface of the stem and extending from the first portion to just below the thermoelectric element, the third portion being provided on the one side on a side surface of the stem; and a plurality of lead pins provided around the second portion and penetrating through the stem from the upper surface to the rear surface.

### FIELD

The present disclosure relates to a semiconductor laser device.

### BACKGROUND

PTL 1 discloses a CAN package-type optical module including a stem that includes a first surface connected to a flexible substrate and a second surface as a surface on a side opposite to the first surface. A signal pin penetrates through the stem from the first surface to the second surface, and protrudes from the first surface. An insulating material is filled in between the stem and the signal pin. An optical semiconductor is connected to the signal pin on the second surface side of the stem. A ground pin is provided on the first surface.

### CITATION LIST

### Patent Literature

[PTL 1] JP 6825756 B

### SUMMARY

### Technical Problem

In a semiconductor laser device as disclosed in PTL 1, characteristics of a semiconductor laser are generally changed by a temperature. To stably maintain the characteristics of the semiconductor laser even in a case where an environmental temperature is changed, a thermoelectric element is generally incorporated in the semiconductor laser device, and the temperature of the semiconductor laser is controlled to be constant. The thermoelectric element is required to discharge heat generated by the thermoelectric element itself, in addition to, for example, heat generated by the semiconductor laser, and inflow heat from outside through lead pins and wires.

To reduce a price, a CAN package using a stem is applied to the semiconductor laser device incorporating such a thermoelectric element, in some cases. However, heat dissipation from the stem is generally difficult because of the shape. When a heat generation amount of the semiconductor laser is increased in response to a high light output request to the semiconductor laser, it is anticipated that it is further difficult to keep the temperature of the semiconductor laser constant over a wide temperature range.

An object of the present disclosure is to provide a semiconductor laser device that can achieve excellent heat dissipation characteristics.

### Solution to Problem

A semiconductor laser device according to the present disclosure includes a stem; a thermoelectric element provided at a position shifted to one side from a center of the stem, on an upper surface of the stem: a semiconductor laser configured to be temperature-controlled by the thermoelectric element: a heat dissipation block including a first portion, a second portion, and a third portion, the first portion being provided on the one side on a side opposite to the upper surface of the stem and being at least partially provided on a rear surface on the side opposite to the upper surface of the stem, the second portion being provided on the rear surface of the stem and extending from the first portion to just below the thermoelectric element, the third portion being provided on the one side on a side surface of the stem; and a plurality of lead pins provided around the second portion and penetrating through the stem from the upper surface to the rear surface.

### Advantageous Effects of Invention

In the semiconductor laser device according to the present disclosure, the heat dissipation path from the thermoelectric element to the side surface of the stem can be shortened. In addition, the contact area between the stem and the heat dissipation block can be largely secured. This makes it possible to achieve excellent heat dissipation characteristics.

### BRIEF DESCRIPTION OF DRAWINGS

FIG. 1 is a side view of a semiconductor laser device according to Embodiment 1.

FIG. 2 is a cross-sectional view of the semiconductor laser device according to Embodiment 1.

FIG. 3 is a bottom view of the semiconductor laser device according to Embodiment 1.

FIG. 4 is a side view of a semiconductor laser device according to a comparative example.

FIG. 5 is a cross-sectional view of the semiconductor laser device according to the comparative example.

FIG. 6 is a bottom view of the semiconductor laser device according to the comparative example.

FIG. 7 is a cross-sectional view of a semiconductor laser device according to Embodiment 2.

FIG. 8 is a bottom view of the semiconductor laser device according to Embodiment 2.

FIG. 9 is a cross-sectional view of a semiconductor laser device according to a modification of Embodiment 2.

FIG. 10 is a cross-sectional view of a semiconductor laser device according to Embodiment 3.

FIG. 11 is a bottom view of the semiconductor laser device according to Embodiment 3.

FIG. 12 is a cross-sectional view of a semiconductor laser device according to Embodiment 4.

FIG. 13 is a bottom view of the semiconductor laser device according to Embodiment 4.

FIG. 14 is a side view of a semiconductor laser device according to Embodiment 5.

FIG. 15 is a cross-sectional view of the semiconductor laser device according to Embodiment 5.

FIG. 16 is a bottom view of the semiconductor laser device according to Embodiment 5.

### DESCRIPTION OF EMBODIMENTS

A semiconductor laser device according to each embodiment will be described with reference to the drawings. Identical or corresponding constitutional elements are given the same reference numerals, and the repeated description of such constitutional elements may be omitted.

### Embodiment 1

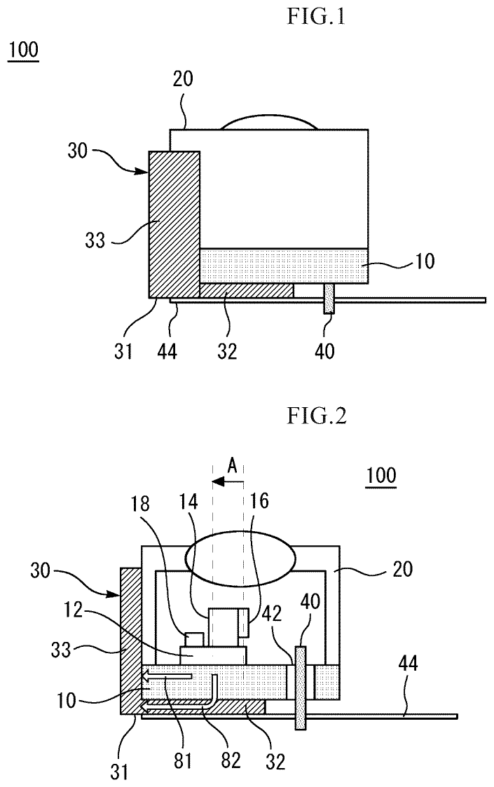

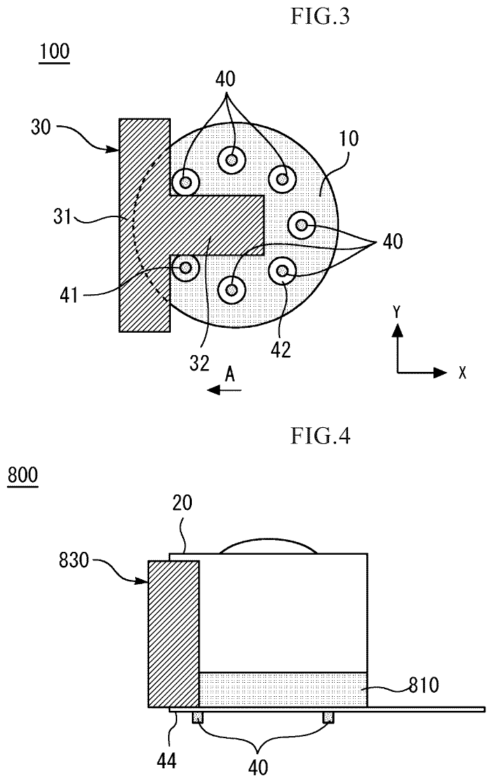

FIG. 1 is a side view of a semiconductor laser device 100 according to Embodiment 1. FIG. 2 is a cross-sectional view of the semiconductor laser device 100 according to Embodiment 1. FIG. 3 is a bottom view of the semiconductor laser device 100 according to Embodiment 1. The semiconductor laser device 100 is provided in a CAN package. In the semiconductor laser device 100, a thermoelectric element 12 is mounted on an upper surface of a stem 10. A carrier 14 mounted with a semiconductor laser 16, and a thermistor 18 are mounted on an upper surface of the thermoelectric element 12.

The semiconductor laser 16 converts electric signals into optical signals. The semiconductor laser 16 is temperature-controlled by the thermoelectric element 12. More specifically, the thermoelectric element 12 is provided to heat or cool the semiconductor laser 16, thereby keeping the temperature of the semiconductor laser 16 constant. The thermistor 18 is mounted near the semiconductor laser 16, and a resistance value thereof is varied based on the temperature.

A plurality of lead pins 40 penetrate through the stem 10 from an upper surface to a rear surface on a side opposite to the upper surface. The lead pins 40 are provided to feed power to the semiconductor laser 16 or the thermoelectric element 12. Gaps between the lead pins 40 and the stem 10 are filled with insulators 42 such as glass. The stem 10 and the plurality of lead pins 40 are insulated by the insulators 42, and are not electrically connected to each other. A ground pin 41 is electrically connected to the stem 10.

A flexible substrate 44 is connected to the lead pins 40 and the ground pin 41. Further, a wiring pattern for electric connection with an optical transceiver is provided on the flexible substrate 44. A heat dissipation block 30 for dissipating heat from the thermoelectric element 12 is provided on a side surface and a bottom surface of the stem 10. On the upper surface side of the stem 10, the semiconductor laser 16 is covered with a cap 20. The cap 20 includes a taking-out window for the optical signals, such as a lens, and airtightly seals the semiconductor laser 16. In the following bottom views, the flexible substrate 44 is omitted in some cases for description of a shape of the heat dissipation block 30 on the rear surface side of the stem 10.

The thermoelectric element 12 is provided at a position shifted to one side from a center of the stem 10, on the upper surface of the stem 10. The one side is a side indicated by an arrow A in FIGS. 2 and 3. The heat dissipation block 30 includes a first portion 31, a second portion 32, and a third portion 33. The first portion 31 is provided on the one side indicated by the arrow A on the rear surface side of the stem 10. At least a part of the first portion 31 is provided on the rear surface of the stem 10. The second portion 32 is provided on the rear surface of the stem 10, and extends from the first portion 31 to just below the thermoelectric element 12. The first portion 31 is a portion extending in a Y direction in FIG. 3, and the second portion 2 is a portion extending in an X direction in FIG. 3. The heat dissipation block 30 has a T-shape on the rear surface of the stem 10. The third portion 33 is provided on the one side indicated by the arrow A on the side surface of the stem 10. As illustrated in FIG. 2, the heat dissipation block 30 has an L-shape in a sectional view.

The plurality of lead pins 40 are provided around the second portion 32 in a planar view. The plurality of lead pins 40 are arranged, for example, on a circumference in a planar view. The plurality of lead pins 40 may be arranged in an arc shape. The second portion 32 is provided so as to enter a region surrounded by the plurality of lead pins 40. The first portion 31 is provided outside the plurality of lead pins 40. The thermoelectric element 12 is mounted while being offset from the center of the stem 10 in a direction in which the lead pins 40 are not provided, namely, in a direction in which a circle formed by the plurality of lead pins 40 is open.

Next, operation of the semiconductor laser device 100 is described. The semiconductor laser 16 converts electric signals input from the optical transceiver through the flexible substrate 44 and the lead pins 40, into optical signals. The semiconductor laser 16 transmits the converted optical signals from the window of the cap 20. The characteristics such as light output and a wavelength of the semiconductor laser 16 are changed by the temperature. Therefore, depending on a modulation method of the optical signals, signal quality may be drastically deteriorated. The thermoelectric element 12 performs heating or cooling such that the resistance value of the thermistor 18, namely, a detected temperature becomes constant. This makes it possible to keep the temperature of the semiconductor laser 16 constant, and to perform control so as not to change the characteristics of the semiconductor laser 16 even when an environmental temperature is changed.

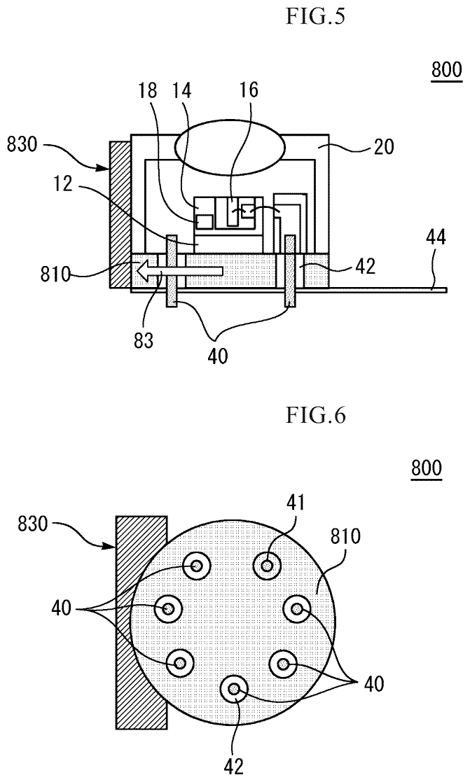

FIG. 4 is a side view of a semiconductor laser device 800 according to a comparative example. FIG. 5 is a cross-sectional view of the semiconductor laser device 800 according to the comparative example. FIG. 6 is a bottom view of the semiconductor laser device 800 according to the comparative example. In the comparative example, the plurality of lead pins 40 are arranged in a circular shape in a planar view. The thermoelectric element 12 is mounted at a center of a stem 810. A heat dissipation block 830 is in thermal contact with a side surface of the stem 810 but is not in contact with a rear surface. A surface of the heat dissipation block 830 on a side opposite to a surface in contact with the stem 810 is a heat dissipation surface for dissipating heat generated by the semiconductor laser device 800 by coming into thermal contact with a heatsink of the optical transceiver.

The heat discharged from the thermoelectric element 12 mainly includes heat generated by the semiconductor laser 16, inflow heat flowing by heat conduction through the lead pins and the like, and heat generated by the thermoelectric element 12 itself. A heat dissipation path from the thermoelectric element 12 is a path reaching the heat dissipation block 830 from the side surface of the stem 810 through the thermoelectric element 12 and the stem 810, as indicated by an arrow 83. The semiconductor laser device 800 according to the comparative example has only one heat dissipation path indicated by the arrow 83. Further, since the thermoelectric element 12 is mounted at the center of the stem 810, the heat dissipation path from the thermoelectric element 12 to the side surface of the stem 810 is long. In addition, the insulators 42 made of glass having extremely low heat conductivity are present on the way of the heat dissipation path. Therefore, the heat dissipation path becomes narrow, and the heat may not be efficiently discharged.

In contrast, in the present embodiment, the heat dissipation block 30 is in thermal contact with the rear surface and the side surface of the stem 10. This makes it possible to largely secure a contact area between the stem 10 and the heat dissipation block 30. Accordingly, the heat resistance can be reduced, and the heat can be efficiently dissipated. In addition, the first portion 31 and the second portion 32 of the heat dissipation block 30 are in contact with the rear surface of the stem 10. This makes it possible to further largely secure the contact area between the stem 10 and the heat dissipation block 30. In the present embodiment, the surface of the third portion 33 of the heat dissipation block 30 on the side opposite to the stem 10 serves as the heat dissipation surface coming into thermal contact with the heatsink of the optical transceiver. As the heat dissipation path, the path reaching the heat dissipation block 30 from the side surface of the stem 10 through the thermoelectric element 12 and the stem 10 is provided as indicated by an arrow 81. Further, as indicated by an arrow 82, a path reaching the heat dissipation block 30 from the rear surface of the stem 10 through the thermoelectric element 12 and the stem 10 is provided. As described above, in the present embodiment, two heat dissipation paths can be secured.

The thermoelectric element 12 is provided at the position shifted toward the third portion 33 of the heat dissipation block 30 from the center of the stem 10. This makes it possible to shorten the heat dissipation path from the thermoelectric element 12 to the side surface of the stem 10. Furthermore, the plurality of lead pins 40 are provided while avoiding positions of the stem 10 overlapping with the heat dissipation block 30 in a planar view. In other words, no insulator 42 is provided at the position of the stem 10 overlapping with the heat dissipation block 30 in a planar view. Therefore, the insulator 42 made of glass having extremely low heat conductivity is not provided on the way of the heat dissipation path, which makes it possible to efficiently dissipate heat. Since the rear surface shape of the heat dissipation block 30 is the T-shape, the second portion 32 can cover a portion just below the thermoelectric element 12, of the rear surface of the stem 10. This makes it possible to efficiently transfer the heat from just below the thermoelectric element 12 to the heat dissipation surface. Accordingly, in the present embodiment, excellent heat dissipation characteristics can be achieved.

Further, since the cross-sectional shape of the heat dissipation block 30 is the L-shape, the heat dissipation block 30 can be easily attached to the stem 10. The heat dissipation block 30 according to the present embodiment is a single member and can come into contact with the side surface and the rear surface of the stem 10.

To improve thermal contact, a gap between the heat dissipation block 30 and each of the side surface and the rear surface of the stem 10 may be filled with gel or an adhesive excellent in heat conductivity. In FIG. 1, the heat dissipation block 30 extends up to a vicinity of an upper surface of the cap 20. This makes it possible to transfer slight heat dissipation from the cap 20 to the heat dissipation block 30, and to secure attachment stability of the semiconductor laser device 100 to the optical transceiver.

As a modification of the present embodiment, the plurality of lead pins 40 may not be arranged on the circumference. It is sufficient for the plurality of lead pins 40 to be arranged so as not overlap with the heat dissipation block 30. The number of the plurality of lead pins 40 is not limited. Further, the structure of the heat dissipation block 30 is not limited to the structure illustrated in FIGS. 1 to 3. The heat dissipation block 30 may not have the T-shape on the rear surface of the stem 10. Further, depending on required heat dissipation characteristics, the second portion 32 may not extend up to just below the thermoelectric element 12.

These modifications can be applied, as appropriate, to semiconductor laser devices according to the following embodiments. Note that the semiconductor laser devices according to the following embodiments are similar to that of the first embodiment in many respects, and thus differences between the semiconductor laser devices according to the following embodiments and that of the first embodiment will be mainly described below.

### Embodiment 2

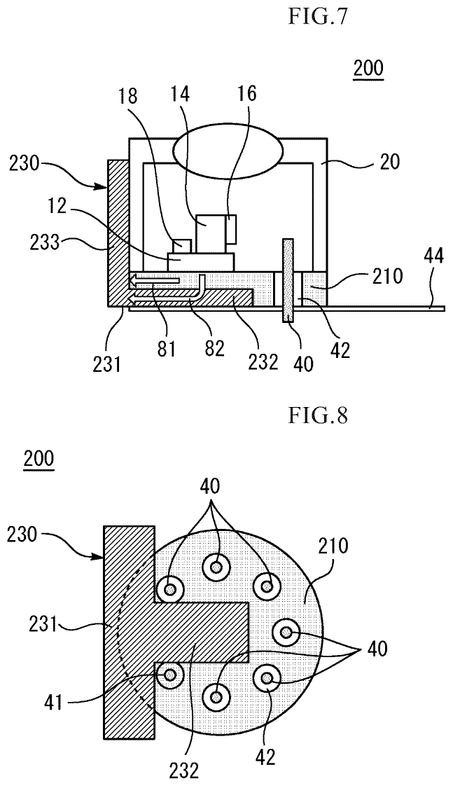

FIG. 7 is a cross-sectional view of a semiconductor laser device 200 according to Embodiment 2. FIG. 8 is a bottom view of the semiconductor laser device 200 according to Embodiment 2. In the present embodiment, structures of a stem 210 and a heat dissipation block 230 are different from the structures of the stem 10 and the heat dissipation block 30 according to Embodiment 1. The other configurations are similar to the configurations according to Embodiment 1. A portion of the stem 210, a rear surface of which is in contact with the heat dissipation block 230, is thinner than the other portions of the stem 210.

The heat dissipation block 230 includes a first portion 231, a second portion 232, and a third portion 233 as in Embodiment 1. The heat dissipation block 230 is higher in thermal conductivity than the stem 210. A material of the stem 210 is, for example, iron having thermal conductivity of 80 W/m/K. In this case, as a material of the heat dissipation block 230, for example, copper having thermal conductivity of 398 W/m/K or aluminum having thermal conductivity of 237 W/m/K can be used.

A material having thermal conductivity higher than the thermal conductivity of the stem 210 is used for the heat dissipation block 230, and the stem 210 is made thin. This makes it possible to efficiently dissipate heat from the rear surface of the stem 210. Further, a protrusion of the heat dissipation block 230 to the rear surface of the stem 210 can be reduced. As a result, the flexible substrate 44 can be connected to roots of the lead pins 40 and the ground pin 41. Accordingly, it is possible to accelerate modulation characteristics of the semiconductor laser device 200.

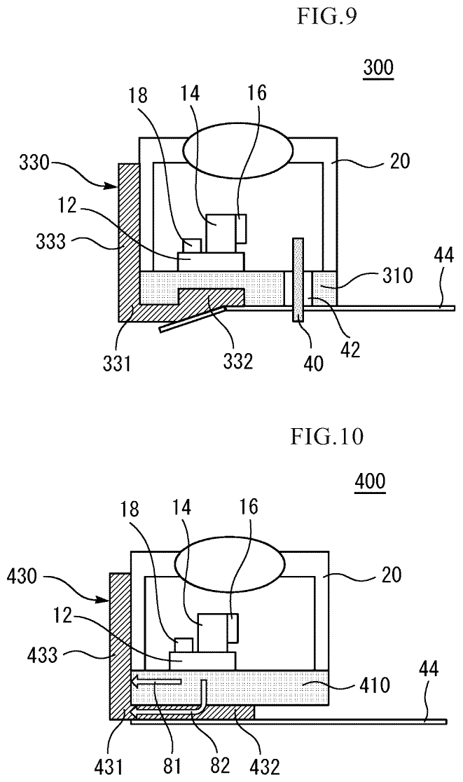

FIG. 9 is a cross-sectional view of a semiconductor laser device 300 according to a modification of Embodiment 2. The semiconductor laser device 300 includes a stem 310 and a heat dissipation block 330. The heat dissipation block 330 includes a first portion 331, a second portion 332, and a third portion 333 as in Embodiment 1. In the modification, at least a part of a portion of the stem 310, a rear surface of which is in contact with the heat dissipation block 330, is thinner than the other portions of the stem 310. In the example in FIG. 9, only a portion of the stem 310 just below the thermoelectric element 12 is made thin. Even in this case, effects similar to the effect in Embodiment 2 are achievable.

### Embodiment 3

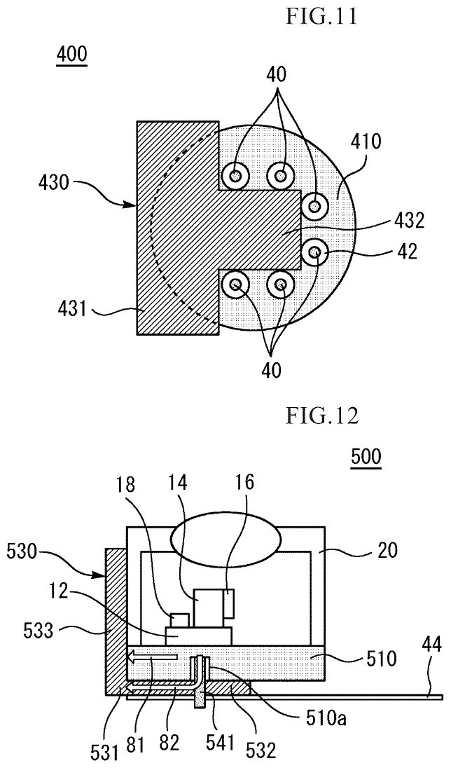

FIG. 10 is a cross-sectional view of a semiconductor laser device 400 according to Embodiment 3. FIG. 11 is a bottom view of the semiconductor laser device 400 according to Embodiment 3. The semiconductor laser device 400 includes a stem 410 and a heat dissipation block 430. The heat dissipation block 430 includes a first portion 431, a second portion 432, and a third portion 433 as in Embodiment 1. The present embodiment is different from Embodiment 1 in that no ground pin 41 is provided. Further, the stem 410, the heat dissipation block 430, and a joint member joining the stem 410 and the heat dissipation block 430 each have electric conductivity. A gap between the heat dissipation block 430 and each of a side surface and a rear surface of the stem 410 is filled with the joint member. To realize excellent thermal contact and excellent electric contact, the joint member is preferably gel or an adhesive having heat conductivity and electric conductivity.

The stem 410 according to the present embodiment includes no ground pin. However, since the heat dissipation block 430, the stem 410, and the joint member have electric conductivity, grounding can be performed by the heat dissipation block 430. In other words, the heat dissipation block 430 serves as a grounding terminal for the semiconductor laser 16. Further, since the stem 410 includes no ground pin 41, a width of a portion where the lead pins 40 are not arranged can be enlarged as compared with Embodiment 1. Therefore, it is possible to increase the contact area between the rear surface of the stem 410 and the heat dissipation block 430, and to further efficiently dissipate heat.

### Embodiment 4

FIG. 12 is a cross-sectional view of a semiconductor laser device 500 according to Embodiment 4. FIG. 13 is a bottom view of the semiconductor laser device 500 according to Embodiment 4. The semiconductor laser device 500 includes a stem 510 and a heat dissipation block 530. The heat dissipation block 530 includes a first portion 531, a second portion 532, and a third portion 533 as in Embodiment 1. On a rear surface of the stem 510, a concave portion 510a is provided at a portion just below the thermoelectric element 12. A ground pin 541 is inserted into the concave portion 510a.

The ground pin 541 is attached to the concave portion 510a of the stem 510 while being electrically connected to the stem 510 by means such as welding, brazing, and soldering. The ground pin 541 is higher in thermal conductivity than the stem 510. A material of the stem 510 is, for example, iron having thermal conductivity of 80 W/m/K. In this case, a material of the ground pin 541 is, for example, copper having thermal conductivity of 398 W/m/K or aluminum having thermal conductivity of 237 W/m/K.

The ground pin 541 penetrates through the heat dissipation block 530. A hole through which the ground pin 541 passes is provided in the heat dissipation block 530. To secure thermal contact, a gap between the ground pin 541 and the heat dissipation block 530 is filled with gel or an adhesive excellent in heat conductivity.

In the present embodiment, heat from the thermoelectric element 12 can be discharged to the heat dissipation block 530 through the ground pin 541. Accordingly, heat can be efficiently dissipated from the rear surface of the stem 510. Further, as in Embodiment 4, a width of a portion where the lead pins 40 are not arranged can be enlarged. Therefore, it is possible to increase the contact area between the rear surface of the stem 510 and the heat dissipation block 530, and to further efficiently dissipate heat.

### Embodiment 5

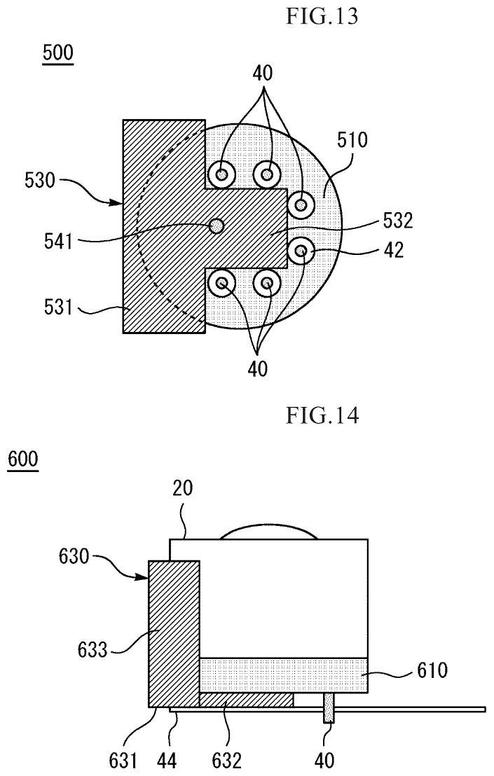

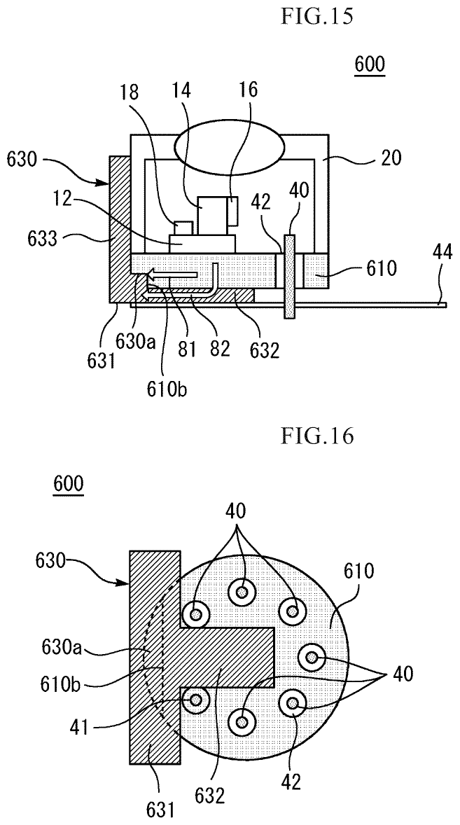

FIG. 14 is a side view of a semiconductor laser device 600 according to Embodiment 5. FIG. 15 is a cross-sectional view of the semiconductor laser device 600 according to Embodiment 5. FIG. 16 is a bottom view of the semiconductor laser device 600 according to Embodiment 5. The semiconductor laser device 600 includes a stem 610 and a heat dissipation block 630. The heat dissipation block 630 includes a first portion 631, a second portion 632, and a third portion 633 as in Embodiment 1. A notch 610b is provided on a side surface of the stem 610. The heat dissipation block 630 includes a protrusion 630a in the third portion 633. The protrusion 630a and the notch 610b are fitted to each other.

The dissipation block according to each of Embodiments 1 to 4 is freely rotatable to a center axis of the stem. Therefore, the heat dissipation surface may be displaced. In the present embodiment, the notch 610b of the stem 610 and the protrusion of the heat dissipation block 630 are fitted to each other, which makes it possible to prevent rotation of the heat dissipation block 630. Further, the heat dissipation surface can be easily directed to a designed direction, and the heat dissipation block 630 can be easily positioned and attached. The heat dissipation block 630 may be made of a material higher in thermal conductivity than the stem 610. As a result, heat can be efficiently dissipated from the notch 610b of the stem 610.

Note that the technical features described in the above embodiments may be combined as appropriate.

### REFERENCE SIGNS LIST

10 stem, 12 thermoelectric element, 14 carrier, 16 semiconductor laser, 18 thermistor, 20 cap, 30 heat dissipation block, 31 first portion, 32 second portion, 33 third portion, 40 lead pin, 41 ground pin, 42 insulator, 44 flexible substrate, 100, 200 semiconductor laser device, 210 stem, 230 heat dissipation block, 231 first portion, 232 second portion, 233 third portion, 300 semiconductor laser device, 310 stem, 330 heat dissipation block, 331 first portion, 332 second portion, 333 third portion, 400 semiconductor laser device, 410 stem, 430 heat dissipation block, 431 first portion, 432 second portion, 433 third portion, 500 semiconductor laser device, 510 stem, 510a concave portion, 530 heat dissipation block, 531 first portion, 532 second portion, 533 third portion, 541 ground pin, 600 semiconductor laser device, 610 stem, 610b notch, 630 heat dissipation block, 630a protrusion, 631 first portion, 632 second portion, 633 third portion, 800 semiconductor laser device, 810 stem, 830 heat dissipation block

1. A semiconductor laser device, comprising:
a stem;
a thermoelectric element provided at a position shifted to one side from a center of the stem, on an upper surface of the stem;
a semiconductor laser configured to be temperature-controlled by the thermoelectric element;
a heat dissipation block including a first portion, a second portion, and a third portion, the first portion being provided on the one side on a side opposite to the upper surface of the stem and being at least partially provided on a rear surface on the side opposite to the upper surface of the stem, the second portion being provided on the rear surface of the stem and extending from the first portion to just below the thermoelectric element, the third portion being provided on the one side on a side surface of the stem; and
a plurality of lead pins provided around the second portion and penetrating through the stem from the upper surface to the rear surface.

2. The semiconductor laser device according to claim 1, wherein
the stem and the plurality of lead pins are isolated by insulators, and
the plurality of lead pins are provided while avoiding positions of the stem overlapping with the heat dissipation block in a planar view.

3. The semiconductor laser device according to claim 1, wherein the plurality of lead pins are arranged on a circumference in a planar view.

4. The semiconductor laser device according to claim 1, wherein
the heat dissipation block is higher in thermal conductivity than the stem, and
at least a part of a portion of the stem, the rear surface of which is in contact with the heat dissipation block, is thinner than other portions of the stem.

5. The semiconductor laser device according to claim 1, wherein
the stem, the heat dissipation block, and a member joining the stem and the heat dissipation block each have electric conductivity, and
the heat dissipation block serves as a grounding terminal for the semiconductor laser.

6. The semiconductor laser device according to claim 1, further comprising a ground pin configured to be inserted into a concave portion provided at a portion just below the thermoelectric element on the rear surface of the stem and to penetrate through the heat dissipation block, and higher in thermal conductivity than the stem.

7. The semiconductor laser device according to claim 1, wherein the side surface of the stem includes a notch, and the third portion and the notch are fitted to each other.
